(19) United States
(12) Patent Application Publication
(10) Pub. No.: US 2026/0005135 A1
(43) Pub. Date: Jan. 1, 2026

(54) INTERCONNECT STRUCTURE WITH HYBRID BOND ANTI-FUSES

(71) Applicant: International Business Machines Corporation, Armonk, NY (US)

(72) Inventors: Nicholas Alexander POLOMOFF, Hopewell Junction, NY (US); Mukta Ghate Farooq, HOPEWELL JCT, NY (US)

(21) Appl. No.: 18/755,906

(22) Filed: Jun. 27, 2024

(51) Int. Cl. H01L 23/525; H01L 23/00

(52) U.S. Cl. CPC H01L 23/5252; H01L 24/05; H01L 24/08; H01L 2224/05647; H01L 2224/08145

(57) ABSTRACT

An interconnect structure includes hybrid-bonded first and second interposers. The first interposer has a first surface including a layer of insulation and a BEOL below the layer of insulation. The layer of insulation has a first recess in the layer exposing a metal conductor of the BEOL, and the first recess is filled with a material changing from nonconducting to conducting upon being heated above a predetermined temperature. The layer of insulation has a second recess in the layer exposing a metal conductor of the BEOL, and the second recess is filled with metal. The second interposer has a similar construction. Upon hybrid bonding, the material that changes from non-conducting to conducting forms an anti-fuse.

### BACKGROUND

The present invention relates to the electrical, electronic, and computer arts, and more specifically, to anti-fuses for use in semiconductor chips.

Fuses are known in the art to switch open or to switch from conducting to nonconducting in response to excessive electrical voltage and/or current which generates heat and/or increases the temperature. Anti-fuses do the opposite of fuses and switch from nonconducting to conducting in response to excessive electrical voltage and/or current which generates heat and/or increases the temperature.

### SUMMARY

Principles of the invention provide techniques for an interconnect structure with hybrid bond anti-fuses. In one aspect, an exemplary interconnect structure includes a first interposer having a first surface including a layer of insulation and a BEOL below the layer of insulation. The layer of insulation has a first recess in the layer exposing a metal conductor of the BEOL. The first recess is filled with a material changing from nonconducting to conducting upon being heated above a predetermined temperature, The layer of insulation has a second recess in the layer exposing a metal conductor of the BEOL. The second recess is filled with metal. A second interposer has a first surface including a layer of insulation and a BEOL below the layer of insulation. The layer of insulation has a first recess in the layer exposing a metal conductor of the BEOL, and the first recess is filled with a material changing from nonconducting to conducting upon being heated above a predetermined temperature. The layer of insulation has a second recess in the layer exposing a metal conductor of the BEOL. The second recess is filled with metal. The material of the first interposer is bonded to the material of the second interposer and the metal of the first interposer is bonded to the metal of the second interposer.

In another aspect, an exemplary apparatus includes a phase change material positioned between first and second metal regions. The first and second metal regions are coupled to first and second respective electrical terminals. A first resistive heat element is positioned for transferring heat to the phase change material. The first resistive heat element is coupled to third and fourth terminals for passing electrical current through the resistive heat element for changing the phase of the phase change material from a nonconductive state to a conductive state.

In yet another aspect, an exemplary anti-fuse apparatus includes a plurality of anti-fuses, and a voltage/current controller coupled to the plurality of anti-fuses for causing each respective anti-fuse to be “on” or in a conductive state from an original “off” or non-conductive state. The voltage/current controller has an input terminal for receiving anti-fuse data indicating the anti-fuses that should be “on” or in a conducting state.

As used herein, “facilitating” an action includes performing the action, making the action easier, helping to carry the action out, or causing the action to be performed. Thus, by way of example and not limitation, instructions executing on one processor might facilitate an action carried out by instructions executing on a remote processor and/or by semiconductor fabrication equipment, by sending appropriate data or commands to cause or aid the action to be performed. Where an actor facilitates an action by other than performing the action, the action is nevertheless performed by some entity or combination of entities.

Techniques as disclosed herein can provide substantial beneficial technical effects. Some embodiments may not have these potential advantages and these potential advantages are not necessarily required of all embodiments. By way of example only and without limitation, one or more embodiments may provide one or more of:
improved yield at wafer, module and final assembly test levels,
flexibility in logic function and system use (e.g., switch anti-fuse from nonconducting to conducting to address problems with subsystems, or altered state of anti-fuse can be used to indicate errors),
mitigation of potential electrical damage at bonding interface,
resistive hardware or electrical regulation to control or manage electrical voltage and currents,
redundancy or backup chips and devices,
use in device security features and functions—can configure circuit so it only operates when anti-fuses become conducting after entering a password or the like,
restrictive and memory programming applications—can access or block memory or the state of the anti-fuse can itself be used to store data in a non-volatile manner,
dynamic real time programming of devices—e.g., change operation of chip while in operation by anti-fuse becoming conducting, and
provide in-chip performance tuning—e.g., change chip behavior by anti-fuse becoming conducting.

These and other features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a cross section view of a first embodiment of the invention.

FIG. 2 is a cross section view illustrating a first process step in forming a second embodiment of the invention.

FIG. 3 is a cross section view illustrating a second process step in forming the second embodiment of the invention.

FIG. 4 is a cross section view illustrating a third process step in forming the second embodiment of the invention.

FIG. 5 is a cross section view of anti-fuse shown in FIG. 1 in the “off” state changing to the “on” state.

FIG. 6 is a cross section view of anti-fuse shown in FIG. 1 in the “on” state.

FIG. 7 is a cross section view of a second embodiment of the invention in the “off” state.

FIG. 8 is a cross section view of a second embodiment of the invention in the “on” state.

FIG. 9 is a block diagram of a third embodiment of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Aspects of the invention relate to anti-fuses for use in semiconductor chips. One or more embodiments advantageously provide an anti-fuse including a phase change material (PCM) responsive to application of energy (e.g., thermal, electrical) and/or temperature to switch from a nonconducting state to a conducting state.

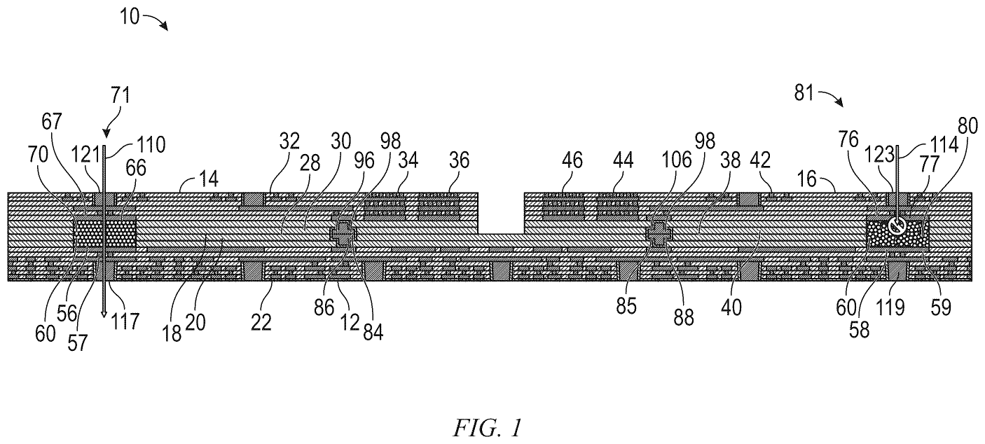

Referring now to the drawings, FIG. 1 is a cross section view of an interconnect structure 10 having a first interposer 12, a second interposer 14, and a third interposer 16. First interposer 12 has a first surface 18, a first layer of insulation 20 having and back end of the line (BEOL) wiring 22 below the layer of insulation 20. BEOL 22 has a plurality of metal interconnect layers spaced apart by respective insulation layers and interconnected between metal layers by metal vias.

Second interposer 14 has a first surface 28, a first layer of insulation 30 and back end of the line (BEOL) wiring 32 above the layer of insulation 30. Second interposer 14 has crack stop structures 34 and 36 to prevent cracks from propagating into the BEOL 32. Third interposer 16 has a first surface 38, a first layer of insulation 40 and back end of the line (BEOL) wiring 42 above the layer of insulation 40. Third interposer 14 has crack stop structures 44 and 46 to prevent cracks from propagating into the BEOL 42.

First interposer 12 has first and second recesses 56, 58 filled with a material 60 which changes from nonconducting to conducting upon being heated above a predetermined temperature. Second interposer 14 has a first recess 66 positioned above recess 56 filled with material 70 which is bonded to material 60. Third interposer 16 has a first recess 76 positioned above recess 58 filled with material 80 which is bonded to material 60. Materials 60, 70, and 80 change from nonconducting to conducting upon being heated above a predetermined temperature.

First interposer 12 has third and fourth recesses 86, 88 in insulation layer 20 filled with metal 84 and 85 respectively suitable for hybrid bonding (e.g., Cu). Second interposer 14 has a second recess 96 in insulation layer 30 positioned above recess 86 filled with metal 98 which is bonded to metal 84. Third interposer 16 has a second recess 106 in insulation layer 40 positioned above recess 88 filled with metal 98 which is bonded to metal 85 (which can, for example, be the same as metal 84).

In FIG. 1, interposer 14 is aligned with interposer 12 with surfaces 18 and 28 previously planarized. The interposers are then brought together with heat and pressure and are hybrid bonded together with insulation layer 30 bonded to insulation layer 20, material 70 bonded to material 60, and metal 98 bonded to metal 84. Likewise, interposer 16 is aligned with interposer 12 with surfaces 18 and 38 previously planarized. The interposers are then brought together with heat and pressure and are hybrid bonded together with insulation layer 40 bonded to insulation layer 20, material 80 bonded to material 60, and metal 98 bonded to metal 85.

In hybrid bonding, a permanent bond combines a dielectric bond (e.g., SiOx) with embedded metal (e.g., Cu) to form interconnections. Two interconnect structures or semiconductor builds are joined together (e.g., two individual wafers that are built separately). They typically require a “pristine” surface (smooth and flat, possibly with some recesses), more so than traditional chemical-mechanical planarization (CMP). The two semiconductor builds are purposely designed to align. The term “hybrid” refers to the presence of both copper and dielectric. A bond that uses dielectric alone is referred to as fusion bonding (oxide to oxide). Hybrid bonding uses metal to metal connections for the copper. Two semiconductor builds 12 and 14 and/or 12 and 16 are brought together and a small heat treatment/annealing process is carried out. The oxides bond together and the metals “anneal,” or almost melt, together, thus fusing the interface into a single bonded part (in some instances, seamlessly; i.e., the interface line disappears).

Materials 60, 70, and 80 can be, for example, a phase change material (PCM) that changes crystalline phase, or changes from amorphous to crystalline phase and in that phase becomes electrically conductive, or that undergoes a transition from an insulating phase to a conducting phase upon an application of energy or force (temperature, pressure, electrical (Joule heating)). Si is a material that undergoes a transition from amorphous silicon (a-Si) to crystalline silicon (c-Si) with a corresponding change from insulating to electrical conductivity. Other materials that undergo a transition include doped Si, metal silicides, transition metal oxides such as Vanadium dioxide (VO2), Graphene Oxide, Polymeric Nanocomposites (doped with nanoparticles, carbon nanotubes, graphene), metal organic frameworks (MOFs)), Chalcogenide glasses (e.g., GST (GeSbTe/germanium-antimony-tellurium)), and Perovskite Oxides which exhibit phase change behavior and change in electrical conductivity.

It is worth noting that the PCM regions that are to be bonded or merged together should be the same materially. Realistically, for ease of manufacturing, all PCM regions can be the same material across the build. However, if desired, it is possible through processing to create structures that are made from different PCM choices. In this latter case, however, each half of the structure should be the same—so when the halves are merged it is all the same material.

As shown in FIG. 1, materials 60 and 70 are bonded together to form anti-fuse 71. Materials 60 and 70 on the left-hand side are crystalline as indicated by the rows and columns of circles in an ordered manner. Arrow 110 indicates that materials 60 and 70 are in the conductive state. Materials 60 and 80 are bonded together to form anti-fuse 81. Materials 60 and 80 on the right-hand side are amorphous or non-crystalline as indicated by the disorder of the atoms (circles shown) with no organized arrangement of rows or columns of atoms (circles shown). Arrow 114 indicates that materials 60 and 80 are in the non-conductive state.

BEOL 22 has metal region 57 and 59 at the bottom of recesses 56 and 58 respectively coupled to metal 117 and 119 for conducting electrical current to and from materials 60 and 70 and materials 60 and 80 respectively. BEOL 32 has metal 67 at the bottom of recess 66 coupled to metal 121 for conducting electrical current to and from material 60 and 70. BEOL 42 has metal region 77 at the bottom of recess 76 coupled to metal 123 for conducting electrical current to and from materials 60 and 80. BEOL 32 has metal region 67 at the bottom of recess 66 coupled to metal 121 for conducting electrical current to and from materials 60 and 70.

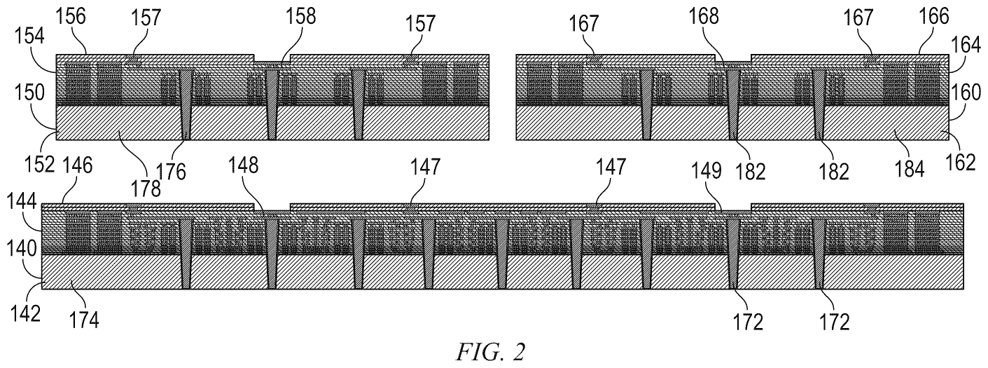

In FIG. 2, and in subsequent figures, like reference numerals are used for structures and functions corresponding to the description in an earlier figure.

FIG. 2 is a cross sectional view illustrating a process step in forming an anti-fuse device. A first interposer 140 is shown having a substrate 142, BEOL wiring 144, an insulation layer 146, metal regions 147 in insulation layer 146 and two open cavities or recessed regions 148 and 149 in insulation layer 146. A second interposer 150 is shown having a substrate 152, BEOL 154, an insulation layer 156, metal regions 157 in insulation layer 156 and an open cavity or recessed region 158 in insulation layer 146. A third interposer 160 is shown having a substrate 162, BEOL wiring 164, an insulation layer 166, metal regions 167 in insulation layer 166 and an open cavity or recessed region 168 in insulation layer 166. First interposer 140 has through silicon vias (TSV) or through insulator vias (TIV) 172 to the backside or surface 174. Second interposer 150 has through silicon vias (TSV) or through insulator vias (TIV) 176 to the backside or surface 178. Third interposer 160 has through silicon vias (TSV) or through insulator vias (TIV) 182 to the backside or surface 184.

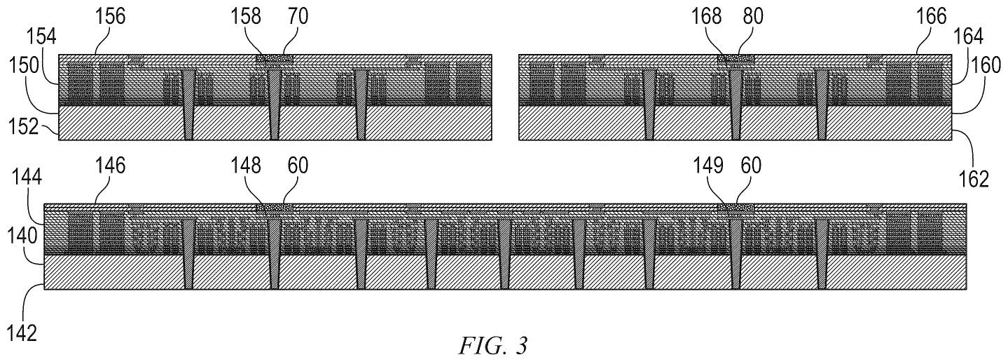

FIG. 3 is a cross sectional view illustrating a subsequent step in forming an anti-fuse device. Material 60 is deposited in open cavities or recessed regions 148 and 149. Material 70 is deposited in open cavity or recessed region 158. Material 80 is deposited in open cavity or recessed region 168. The upper surface of insulation layers 146, 156, and 166 are planarized for hybrid bonding in the next step.

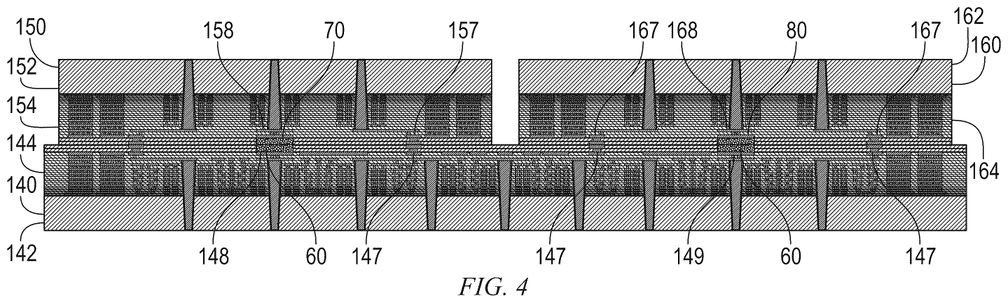

FIG. 4 is a cross sectional view illustrating a subsequent step in forming an anti-fuse device. Interposer 150 is flipped upside down and aligned so recessed region 158 and material 70 are over recess region 148 and material 60. Furthermore, metal region 157 is aligned with metal region 147. Interposer 160 is flipped upside down and aligned so recessed region 168 and material 80 are over recessed region 149 and material 60. Furthermore, metal region 167 is aligned with metal region 147. The metal regions and insulation surfaces are then hybrid bonded together in a heat treatment process to form a hybrid bonded interface for material 60 and 70; material 60 and 80; insulation layers 146, 156, and 166; and metal regions 147, 157, and 167 as shown in FIG. 4.

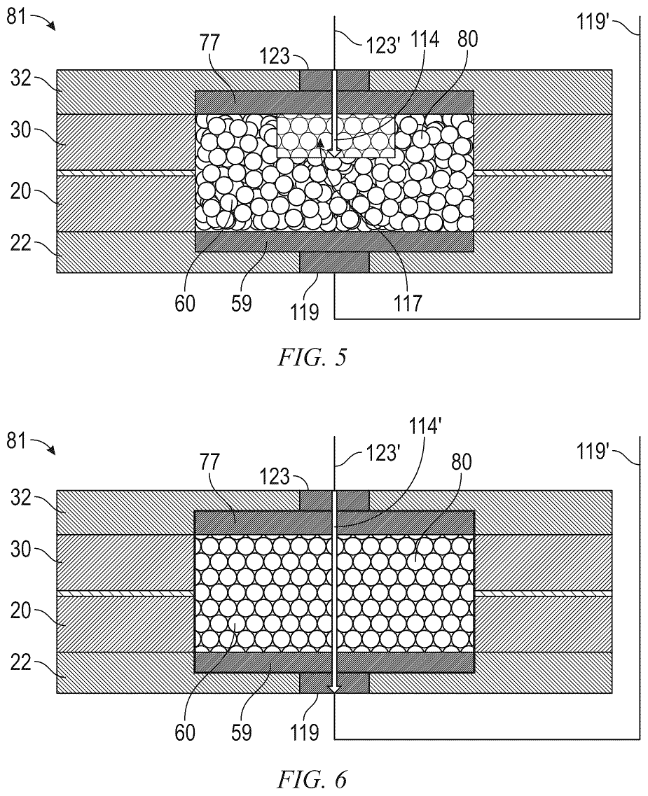

FIG. 5 is a cross sectional view of anti-fuse or memory device 81 shown in FIG. 1 which is in the process of switching from an “off” state to an “on” state. A sufficient or preselected voltage and/or current is applied to lead 123′ and metal 123 which causes a current to flow into and through material 80 and 60 shown by arrow 114 to metal 119 and lead 119′. As the current flows at the sufficient or preselected voltage and/or current, power is expended or dissipated in material 80 and 60 in the form of Joule Heating which raises the temperature as a function of power and time as the heat spreads through material 80 and 60 and the surrounding structure, thus raising the temperature. Materials 80 and 60 can be, for example, Si originally in the amorphous state or phase and in the “off” state and nonconductive. As the temperature rises above a predetermined temperature, atoms of Si begin to organize or nucleate into crystals 117 which in turn organizes nearby Si atoms and the Si crystals (the material rearranges and becomes more ordered). As time continues and the heat spreads, more of materials 80 and 60 become crystalline Si and conductive.

If anti-fuse or memory device 81 is calibrated correctly, an electrical path can be created in phase change material 60 and 80 during the application of one or more external stimuli to lead 123′, meaning it is only electrically conductive upon the application of a sufficient external stimulus, but “off” or nonconductive if an insufficient amount of, or no energy, is provided.

FIG. 6 shows anti-fuse or memory device 81 with material 80 and 60 completely converted from amorphous Si to conductive crystalline Si. The crystalline phase is stable so long as it is kept below the melting temperature of Si, which is 2,577 degrees Centigrade.

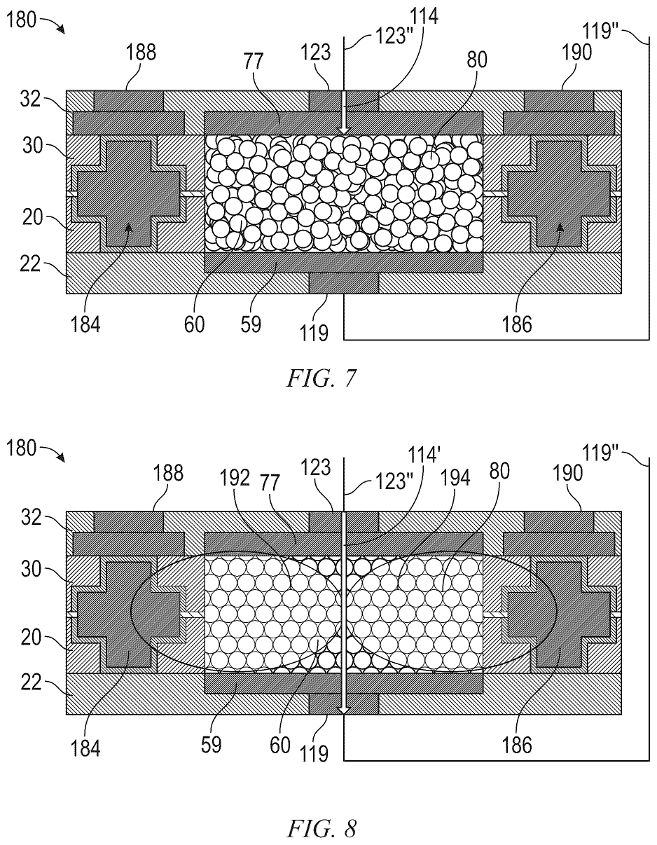

FIG. 7 is a cross sectional view of a second embodiment of the invention showing an anti-fuse device 180 and resistive heat elements 184 and 186 positioned on either side of materials 60 and 80 for heating material 60 and 80 to a selected temperature for a selected time. Resistive heat elements 184 and 186 may be positioned above and below material 60 and 80 or on either side or as well as both arrangements, and it is even possible to add additional heating elements in nearby proximity. The electrical current or resistive heating is electrically independent of any current which flows through material 60 and 80 which initially has disordered atoms in an amorphous state or phase and is in an “off” state and nonconductive. Note the lead 119″.

The voltage and current applied as an electrical signal to leads 188 and 190 determines the amount of heat generated in resistive heat elements 184 and 186. The flow of heat to the phase change material 60 and 80 and the time duration which increases its temperature are pertinent factors in the operation of phase change material 60 and 80. The phase change material phenomenon can be sped up with appropriate bursts of sufficient electrical signal or made more gradual with a smaller energy per electrical signal.

The electrical signals and resulting temperature can be used to change or set and reset the state, phases, or conductivity of the phase change material back and forth, and consequently, can be leveraged as binary 1s and 0s. The material can be ‘frozen’ into a state and revert back to the opposite state under proper application of the applied electrical signals to resistive elements 184 and 186.

With regard to required voltages and/or currents to achieve heating for certain time periods, given the teachings herein, the same can be determined, for example, using known thermal analysis techniques such as commercially available finite element software.

High voltage and current on leads 188 and 190 or on lead 123″ generate sufficient heat to melt the phase change material, leading to rapid quenching into the amorphous state. Moderate voltage and current generate enough heat to promote crystallization over a longer time period without melting the material. “High” and “moderate” in this context refer to values that respectively achieve melting/promote crystallization, which, given the teachings herein, can be determined by the materials and geometry for a given case using the aforementioned commercially available finite element software.

The duration of the temperature (heating time) is pertinent in one or more embodiments because it controls whether the material crystallizes or stays amorphous. Short intense pulses (on the order of nanoseconds) create the amorphous state. Longer moderate pulses allow the material to crystallize. Materials 60 and 80 can be set and reset. The operation of a phase change memory typically relies on precise control of the electrical pulses (voltage and current) to manage the temperature rise and its duration. These factors are pertinent to switching the phase of the materials 60 and 80 between amorphous and crystalline states, thereby encoding binary data. This fine control over temperature and time allows phase change material to function effectively as a memory storage technology.

The memory write process for anti-fuse or memory device 81 or 180 is described as follows: to write data, the phase change material 60 and 80 is heated to a high temperature to make it amorphous (by quickly cooling it down) or to a moderate temperature to make it crystalline (by slowly cooling it down).

The memory read process is described as follows: to read data, a small voltage is applied to the phase change material 60 and 80 and its resistance is measured. The resistance level indicates whether the material is in the amorphous state or crystalline state (and thus, what data bit value is stored).

Nonvolatility is obtained when phase change material retains its phase or stored information even when the power is turned off, making it an attractive nonvolatile memory technology.

FIG. 8 is a cross-sectional view of anti-fuse device 180 shown in FIG. 7 with phase change material 60 and 80 completely switched or converted to the “on” or conductive state. Electrical current flows through metal 188 and resistive heat element 184 to provide heat to materials 60 and 80. The flow of heat is shown by volume 192. At the same time, electrical current flows through metal 190 and resistive heat element 186 to provide heat to materials 60 and 80. The flow of heat is shown by volume 194. Materials 60 and 80 have atoms organized in crystal lattices to form crystalline material which is in a conductive “on” state. Resistive heat elements may be resistive metal such as chromium incorporated into one or more layers 20, 30 of the BEOL and have an electrical return lead (not shown) connected to resistive heat elements 184 and 186.

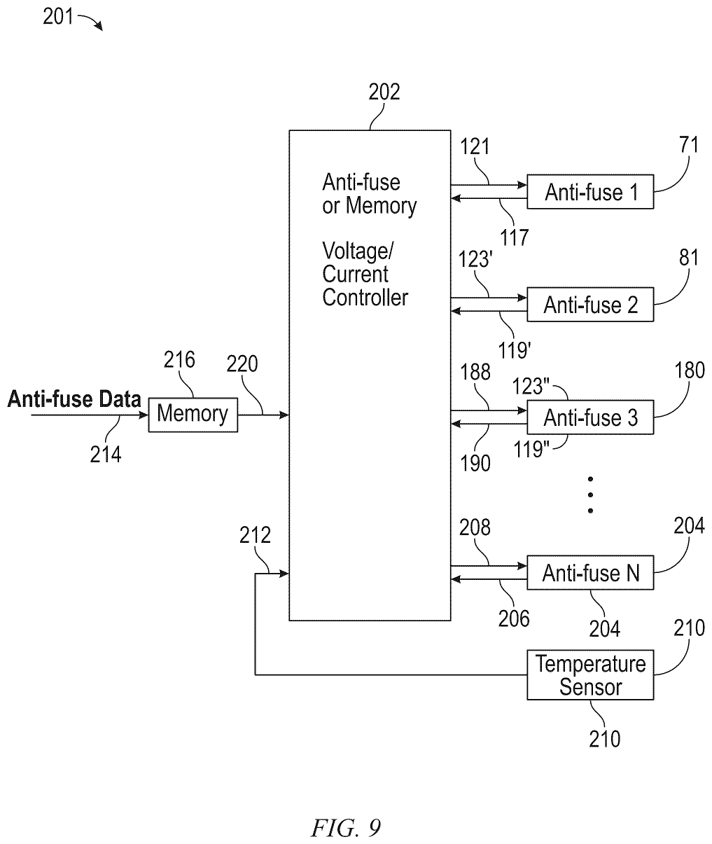

FIG. 9 shows an anti-fuse or nonvolatile memory system 201 including a voltage/current controller 202 connected to anti-fuses 71, 81, 180 and 204 for turning the anti-fuses “on” and “off” or memory bits “on” or “off” (i.e. 1s or 0s respectively) if each anti-fuse device in FIG. 9 represents a memory bit. Anti-fuse 71 is connected over leads 117 and 121. Anti-fuse 81 is connected over leads 119′ and 123′. Anti-fuse 180 is connected over leads 188 and 190 from resistive heat elements 184 and 186 respectively. Leads 119″ and 123″ from anti-fuse 180 connect to an electrical circuit needing an anti-fuse and is isolated from Voltage/Current Controller 202. Anti-fuse 204 is connected over leads 206 and 0208. A temperature sensor 210 (e.g., thermocouple, thermistor) for sensing the temperature near an anti-fuse and/or an ambient temperature is coupled over lead 212 to Voltage/Current Controller 202. Anti-fuse data is coupled over lead 214 to Memory 216. Memory 216 is coupled over lead 220 to Voltage/Current Controller 202. Leads can include cables with multiple conductors as needed.

The Voltage/Current Controller 202 can supply appropriate voltages/currents, and can be integrated or realized as separate power/voltage/current and control units. The Voltage/Current Controller can be implemented in digital circuitry, for example, using computer-aided semiconductor integrated circuit (IC) logic design, simulation, test, layout, and/or manufacture. The computerized design process can represent functional and/or structural design features in a design structure generated using electronic computer-aided design (ECAD). A suitable hardware-description language (HDL) can be employed. The skilled artisan can synthesize digital logic circuits to carry out desired control and other functionality, using known computer-aided design techniques. The Voltage/Current Controller 202 carries out functions as defined herein; given the teachings and description of the functions herein, known control circuit technologies can be employed; e.g., multicycle or pipelined, hardwired or microprogrammed, using any suitable technology family (e.g., 7 nm CMOS, 5 NM CMOS, and the like). For example, the specified functions can be instantiated in logic circuitry using a known design flow process used for example, in semiconductor IC logic design, simulation, test, layout, and manufacture. Such a known design flow for synthesizing digital circuitry includes processes, machines and/or mechanisms for processing design structures or devices to generate logically or otherwise functionally equivalent representations of design structures and/or devices. The design structures processed can be encoded on machine-readable storage media to include data and/or instructions that when executed or otherwise processed on a data processing system generate a logically, structurally, mechanically, or otherwise functionally equivalent representation of hardware components, circuits, devices, or systems. Machines include, but are not limited to, any machine used in an IC design process, such as designing, manufacturing, or simulating a circuit, component, device, or system. For example, machines may include: lithography machines, machines and/or equipment for generating masks (e.g. e-beam writers), computers or equipment for simulating design structures, any apparatus used in the manufacturing or test process, or any machines for programming functionally equivalent representations of the design structures into any medium (e.g. a machine for programming a programmable gate array). Design structures can be generated using ECAD. Use can be made of HDL design entities or other data structures conforming to and/or compatible with lower-level HDL design languages such as Verilog and VHDL, and/or higher level design languages such as C or C++.

Anti-fuse data is coupled over lead 214 to memory 216. The anti-fuse data in memory 216 stores the state of each anti-fuse element and includes any other data such as preferred energy waveform data necessary for voltage/current controller 202 to generate general or customized voltage/current waveforms. Voltage/current controller 202 provides optimum waveforms i.e. energy signals to energize the “on” state for each anti-fuse 71, 81, 180, 204. Anti-fuse 180 can be connected to resistive heat elements 184 and 186. Connection may separately be made to lead 123′ and lead 119′ with optimum waveforms from voltage/current controller 202. Voltage/current controller 202 also receives temperature information over lead 212 from temperature sensor 210 to adjust the optimum waveforms for each anti-fuse 71, 81, 180 and 204. The ambient temperature as well as specific temperatures of each anti-fuse may be monitored by temperature sensor 210. Multiple sensors can be provided for different locations as appropriate.

One or more embodiments thus provide an interconnect structure including two interposers, phase change material (PCM), back end of the line (BEOL) wiring layers, and hybrid bonds. One or more embodiments further provide anti-fuse and non-volatile memory devices including phase change material (PCM).

Semiconductor device manufacturing includes various steps of device patterning processes. For example, the manufacturing of a semiconductor chip may start with, for example, a plurality of CAD (computer aided design) generated device patterns, which is then followed by effort to replicate these device patterns in a substrate. The replication process may involve the use of various exposing techniques and a variety of subtractive (etching) and/or additive (deposition) material processing procedures. For example, in a photolithographic process, a layer of photo-resist material may first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) may experience some changes in their solubility to certain solutions. The photo-resist may then be developed in a developer solution, thereby removing the non-irradiated (in a negative resist) or irradiated (in a positive resist) portions of the resist layer, to create a photo-resist pattern or photo-mask. The photo-resist pattern or photo-mask may subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method may utilize conventional semiconductor fabrication techniques and conventional semiconductor fabrication tooling. These techniques and tooling will already be familiar to one having ordinary skill in the relevant arts given the teachings herein. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1st Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for ease of explanation. This does not imply that the semiconductor layer(s) not explicitly shown are omitted in the actual integrated circuit device.

Given the discussion thus far, referring for example to FIG. 1, it will be appreciated that, in general terms, an exemplary interconnect structure includes a first interposer having a first surface including a layer of insulation and a BEOL below the layer of insulation. The layer of insulation has a first recess in the layer exposing a metal conductor of the BEOL. The first recess is filled with a material changing from nonconducting to conducting upon being heated above a predetermined temperature. The layer of insulation has a second recess in the layer exposing a metal conductor of the BEOL, and the second recess is filled with metal. Also included is a second interposer having a first surface including a layer of insulation and a BEOL below the layer of insulation. The layer of insulation has a first recess in the layer exposing a metal conductor of the BEOL. The first recess is filled with a material changing from nonconducting to conducting upon being heated above a predetermined temperature. The layer of insulation has a second recess in the layer exposing a metal conductor of the BEOL, and the second recess filled with metal. The material of the first interposer is bonded to the material of the second interposer and the metal of the first interposer is bonded to the metal of the second interposer (e.g., hybrid bonding).

The metal can include, for example, copper.

The material that changes from nonconducting to conducting can, for example, be subject to phase change upon being heated above a predetermined temperature. A non-limiting example is silicon which is substantially amorphous in the nonconducting state and substantially polycrystalline in the conducting state.

Referring to FIG. 9, any of the various structures and apparatuses disclosed herein can further include a power source coupled to the material for supplying an electrical current for heating the phase change material above a predetermined temperature (e.g., using a heating element); optionally with a controller coupled to the power source to control the supplying of the electrical current for heating the phase change material above the predetermined temperature.

In another aspect, an exemplary apparatus includes a phase change material positioned between first and second metal regions. The first and second metal regions are coupled to first and second respective electrical terminals. A first resistive heat element is positioned for transferring heat to the phase change material. The first resistive heat element is coupled to third and fourth terminals for passing electrical current through the resistive heat element for changing the phase of the phase change material from a nonconductive state to a conductive state. See FIGS. 7 and 8 for example.

The PCM can be selected from the group consisting of silicon, transition metal oxides including vanadium dioxide, graphene oxide, Polymeric Nanocomposites including those (doped with nanoparticles, carbon nanotubes, and graphene), metal-organic frameworks (MOFs), Chalcogenide glasses, and Perovskite oxides.

In one or more embodiments, the phase change material changes from a conductive state to a nonconductive state by passing electrical current through the resistive heat element for a selected time period.

As explained with respect to FIG. 1, the phase change material can be positioned in one or more insulation layers of a back end of the line (BEOL) of a semiconductor interconnect structure.

As explained with respect to FIG. 1, the first resistive heat element can be positioned in one or more insulation layers of a back end of the line (BEOL) of a semiconductor build.

One or more embodiments further include a second resistive heat element positioned for transferring heat to set phase change material; the second resistive heat element is coupled to 5th and 6th terminals for passing electrical current through the second resistive heat element.

In accordance with further aspects of the invention, referring for example to FIG. 9, an anti-fuse apparatus includes a plurality of anti-fuses, and a voltage/current controller coupled to the plurality of anti-fuses for causing each respective anti-fuse to be “on” or in a conductive state from an original “off” or non-conductive state. The voltage/current controller has an input terminal for receiving anti-fuse data indicating the anti-fuses that should be “on” or in a conducting state. One or more embodiments further include a temperature sensor for indicating the ambient temperature of at least one anti-fuse. One or more embodiments further include a memory for holding anti-fuse data coupled between an anti-fuse data input and the input terminal of the voltage/current controller. In some instances, the plurality of anti-fuses are memory bits including phase change material enclosed within an interposer. One or more embodiments further include data encoded in the plurality of anti-fuses and circuitry for writing/reading same (e.g., part of 202).

Those skilled in the art will appreciate that the exemplary structures discussed above can be distributed in raw form (i.e., a single wafer having multiple unpackaged chips), as bare dies, in packaged form, or incorporated as parts of intermediate products or end products that benefit from use of one or more aspects of the disclosed coaxial TIVs with a lateral metal footing connection for chiplet power signal connection.

An integrated circuit in accordance with aspects of the present inventions can be employed in essentially any application and/or electronic system where one or more aspects of the disclosed coaxial TIVs with a lateral metal footing connection for chiplet power signal connection would be beneficial. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods may occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose can be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. An interconnect structure comprising:
a first interposer having a first surface comprising a layer of insulation and a BEOL below the layer of insulation, the layer of insulation having a first recess in the layer exposing a metal conductor of the BEOL, the first recess filled with a material changing from nonconducting to conducting upon being heated above a predetermined temperature, the layer of insulation having a second recess in the layer exposing a metal conductor of the BEOL, the second recess filled with metal,
a second interposer having a first surface comprising a layer of insulation and a BEOL below the layer of insulation, the layer of insulation having a first recess in the layer exposing a metal conductor of the BEOL, the first recess filled with a material changing from nonconducting to conducting upon being heated above a predetermined temperature, the layer of insulation having a second recess in the layer exposing a metal conductor of the BEOL, the second recess filled with metal, and
wherein the material of the first interposer is bonded to the material of the second interposer and wherein the metal of the first interposer is bonded to the metal of the second interposer.

2. The interconnect structure of claim 1 wherein the metal bonds are hybrid bonds.

3. The interconnect structure of claim 1 wherein the metal bonds comprise copper.

4. The interconnect structure of claim 1 wherein the material is subject to phase change upon being heated above a predetermined temperature.

5. The interconnect structure of claim 1 wherein the material comprises silicon.

6. The interconnect structure of claim 5 wherein the silicon is substantially amorphous in the nonconducting state and substantially polycrystalline in the conducting state.

7. The interconnect structure of claim 1 further includes a power source coupled to the material for supplying an electrical current for heating the phase change material above a predetermined temperature.

8. The interconnect structure of claim 7 further includes a controller coupled to the power source to control the supplying of the electrical current for heating the phase change material above the predetermined temperature.

9. An apparatus comprising:
a phase change material positioned between first and second metal regions, the first and second metal regions coupled to first and second respective electrical terminals, and
a first resistive heat element positioned for transferring heat to the phase change material, the first resistive heat element coupled to third and fourth terminals for passing electrical current through the resistive heat element for changing the phase of the phase change material from a nonconductive state to a conductive state.

10. The apparatus of claim 9 wherein the phase change material is selected from the group consisting of silicon, transition metal oxides including vanadium dioxide, graphene oxide, Polymeric Nanocomposites including those (doped with nanoparticles, carbon nanotubes, and graphene), metal-organic frameworks (MOFs), Chalcogenide glasses, and Perovskite oxides.

11. The apparatus of claim 9 wherein the phase change material changes from a conductive state to a nonconductive state by passing electrical current through the resistive heat element for a selected time period.

12. The apparatus of claim 9 wherein the phase change material is positioned in one or more insulation layers of a back end of the line (BEOL) of a semiconductor interconnect structure.

13. The apparatus of claim 9 wherein the first resistive heat element is positioned in one or more insulation layers of a back end of the line (BEOL) of a semiconductor build.

14. The apparatus of claim 9 further including a second resistive heat element positioned for transferring heat to set phase change material, the second resistive heat element coupled to 5th and 6th terminals for passing electrical current through the second resistive heat element.

15. The apparatus of claim 9 further including a power source coupled to the first resistive heat element to cause the electrical current.

16. The apparatus of claim 15 further including a controller coupled to the power source to control the supplying of the electrical current.

17. An anti-fuse apparatus comprising:
a plurality of anti-fuses, and
a voltage/current controller coupled to the plurality of anti-fuses for causing each respective anti-fuse to be “on” or in a conductive state from an original “off” or non-conductive state, the voltage/current controller having an input terminal for receiving anti-fuse data indicating the anti-fuses that should be “on” or in a conducting state.

18. The anti-fuse apparatus of claim 17 further including a temperature sensor for indicating the ambient temperature of at least one anti-fuse.

19. The anti-fuse apparatus of claim 17 further including a memory for holding anti-fuse data coupled between an anti-fuse data input and the input terminal of the voltage/current controller.

20. The anti-fuse apparatus of claim 17 wherein the plurality of anti-fuses are memory bits comprising phase change material enclosed within an interposer.
